(19) United States
(12) Patent Application Publication
(10) Pub. No.: US 2024/0103377 A1
(43) Pub. Date: Mar. 28, 2024

(54) Etching Composition And Method For EUV Mask Protective Structure

(71) Applicant: Versum Materials US, LLC, Tempe, AZ (US)

(72) Inventors: CHAO-HSIANG CHEN, Hsinchu City (TW); CHUNG-YI CHANG, New Taipei City (TW); YI-CHIA LEE, Chupei City (TW); WEN DAR LIU, Chupei City (TW)

(73) Assignee: Versum Materials US, LLC, Tempe, AZ (US)

(21) Appl. No.: 17/754,816

(22) PCT Filed: Oct. 15, 2020
(86) PCT No.: PCT/US2020/055647

§ 371 Date: Apr. 13, 2022

Related U.S. Application Data
(60) Provisional application No. 62/916,280, filed on Oct. 17, 2019.

(51) Int. Cl. G03F 7/42; G03F 7/20; H01L 21/033

(52) U.S. Cl. CPC G03F 7/423; G03F 7/2004; G03F 7/426; H01L 21/0332

(57) ABSTRACT

A composition and method for removing a metal-containing layer or portion of a layer of a pellicle of an EUV mask are provided. The composition includes water; one or more oxidizing agents; and one or more acids. The method includes forming one or more layers over a silicon substrate with at least one of those layers includes a metal containing layer and removing the metal containing layer by contacting the metal containing layer with the composition of the disclosed and claimed subject matter.

### BACKGROUND

### Field

The disclosed and claimed subject matter relates to extreme ultraviolet (EUV) lithography technology, and more particularly, to a composition and method for fabricating a semiconductor structure on a semiconductor device which includes a metal-containing mask protective structure on said semiconductor device.

### Related Art

As circuit critical dimensions (CD) of semiconductor devices are reduced more and more, physical limitations in using ArF exposure apparatuses to achieve the requisite resolution needed in transferring fine patterns onto wafers have been reached. Accordingly, EUV lithography technology has been developed in order to transfer finer patterns onto wafers. The EUV lithograph technology is considered as a next generation technology which will be used to fabricate a slimmer and faster microchip having a critical dimension of 32 nm or less by using EUV light having about 13.5 nm exposure light wavelength.

In some embodiments, since EUV lithography technology uses light having a very short wavelength, a mask in which circuit patterns to be transferred onto a wafer are preferably provided in mask patterns that do not have light-transmission type structures but rather preferably have light-reflection type structures. Masks used in the EUV lithography processes are likely to include light reflection layers with a multilayer structure of Mo/Si layers on a substrate having a low thermal expansion coefficient (LTE), such as quartz, and a light absorption pattern formed on the light reflection layer that partially expose the surface of the light reflection layer.

A pellicle or protective layer or structure is often provided in order to protect the surface of the EUV mask used in the EUV lithography process from contamination sources such as particles. However, fabrication of such a pellicle that satisfies the demands of EUV lithography is difficult because, among other reasons, it is difficult to use polymers to fabricate a suitable pellicle membrane. In particular, it is well known that carbon-fluorine (C—F) based polymers absorb EUV light, and therefore it is difficult to use C—F based polymers as pellicle membranes. Thus, materials having high transmissivity with respect to the EUV light has been suggested as suitable candidates for pellicle membranes. For example, the following pellicle fabricating method may be employed. A metal layer or mesh of a metal wire such as nickel (Ni) is formed by electroplating, and the layer or mesh is mounted on a polymer film. Silicon (Si) is then deposited to form a silicon membrane layer. Subsequently, the polymer film is removed which results in the silicon membrane layer remaining attached to the mesh. The polymer film is a sacrificial layer.

In addition, in the case of a pellicle for EUV lithography, a thin thickness membrane having a material having high EUV permeability is required, but when a thin thickness membrane is used, a problem arises in that the membrane is deformed and broken by repeated use. In order to solve this problem, pellicle structures have been proposed in which a support structure is added to a thin membrane. The support structure needs to provide high transmittance and mechanical strength.

For example, Korean Patent Registration Publication KR1552940B 1 (Application No. KR20130157275A, Applicant: Samsung Electronics Co., Ltd.) discloses a method for producing a graphite-containing thin film having a high tensile strength while having high EUV permeability with a pellicle film for extreme ultraviolet lithography.

EUV mask protective structures are known that include alternate or additional layers such as a linking layer, a graphene layer of a polycrystalline structure and/or a heat dissipating layer that in some embodiments may be on the linking layer. In one embodiment, disclosed in WO2017183941A1, the EUV pellicle includes a transmissive layer, a graphene layer (graphene layer) on the EUV transmission layer, defects of the graphene layer (providing a linking material on a defect to form a linking pattern, and a heat dissipation layer on the linking pattern and one or more other layers, such as sacrificial layers, insulations layers, passivation layers, for examples, silicon layers, silicon oxide (insulation) or silicon nitride (passivation) layers. But efforts continue to develop EUV pellicles (mask protective structures) and other structures that have excellent mechanical strength, excellent thermal stability, excellent permeability to EUV, and/or excellent hydrogen chemical resistance.

With new EUV mask and mask protective structures being developed, wet compositions to remove the materials in one or more layers after EUV exposure and/or one or more etch steps as well as related residues are needed.

### SUMMARY

The disclosed and claimed subject matter provides a metal etching composition and method that has high removability rates. The etching compositions also provide good compatibility with silicon nitrate (Si₃N₄) and silicon oxide (SiO₂) and other materials on the semiconductor substrate.

In one embodiment, the disclosed and claimed subject matter relates to a composition that includes:
(i) water;
(ii) one or more oxidizing agents; and
(iii) one or more acids,
   wherein the composition is designed for removing a metal-containing layer in a EUV mask protective structure that includes only the metal-containing layer or that further includes one or more additional layers of materials. Thus, in some embodiments the composition for removing a metal-containing layer can includes, can consist essentially of, or alternatively can consist of (i) water; (ii) one or more oxidizing agents and (iii) one or more acids.

In another embodiment, the composition further includes (iv) a halogen ion source. Thus, in some embodiments the composition for removing a metal-containing layer can includes, can consist essentially of, or alternatively can consist of (i) water; (ii) one or more oxidizing agents, (iii) one or more acids and (iv) a halogen ion source.

In another embodiment, the composition further includes (v) a chelating agent. Thus, in some embodiments the composition for removing a metal-containing layer can includes, can consist essentially of, or alternatively can consist of (i) water; (ii) one or more oxidizing agents, (iii) one or more acids and (v) a chelating agent.

In another embodiment, the composition further includes (iv) a halogen ion source and (v) a chelating agent. Thus, in some embodiments the composition for removing a metal-containing layer can includes, can consist essentially of, or alternatively can consist of (i) water; (ii) one or more oxidizing agents, (iii) one or more acids, (iv) a halogen ion source and (v) a chelating agent.

In another embodiment, one or more oxidizing agents (ii) include one or more of peroxomonosulfate, perborate, perchlorate, perchloric acid, peracetate anions, sulfuric acid, periodate, persulfate, permanganate, chromate, dichromate, benzoquinones, nitric acid and amine-N-oxides. In a further aspect of this embodiment, the one or more oxidizing agents (ii) is one or more of ammonium persulfate (APS), 2,5-dihydroxy-1,4-benzoquinone, nitrosyl sulfuric acid, and pyridine N-oxide, 4-methylmorpholine N-oxide.

In another embodiment, one or more acids (iii) include one or more of sulfuric acid, hydrochloric acid, alkyl sulfonic acid, such as, methane sulfonic acid, alkyl benzyl sulfonic acid, such as, 4-methylbenzenesulfonic acid, hydrobromic acid, citric acid, malonic acid, hydrofluoric acid, acetic acid, phosphoric acid, and hydroiodic acid.

In another aspect, the disclosed and claimed subject matter relates to methods for fabricating a semiconductor device that includes the steps of:

a. forming one or more layers over a silicon substrate where at least one of those layers includes a Ni-containing layer; and

b. removing said Ni-containing layer by contacting the Ni-containing layer with at least one of the compositions of the disclosed and claimed subject matter.

In another aspect, the disclosed and claimed subject matter relates to methods of removing a metal-containing layer of a pellicle structure including the steps of:
a. providing a semiconductor device including a substrate and an EUV mask and a metal-containing EUV mask-protecting structure;
b. exposing the semiconductor device to EUV radiation; and
c. removing the metal-containing EUV mask-protecting structure by contacting the semiconductor device with at least one of the compositions of the disclosed and claimed subject matter. In a further aspect of this embodiment, the method includes one or more of the following additional steps:

d. depositing said metal-containing EUV mask-protecting structure on said semiconductor device via atomic layer deposition (ALD), e-beam evaporation, chemical vapor deposition or electroplating; and
e. performing a selective dry etch process on at least one portion of the semiconductor device prior to the removing step c.

In a further aspect of the embodiment for removing a metal-containing layer of a pellicle structure, the metal-containing EUV mask-protecting structure includes nickel. In another aspect, the metal-containing EUV mask-protecting structure includes a metal-containing heat dissipation layer. In another aspect, the metal-containing EUV mask-protecting structure includes a metal-containing linking layer. In another aspect, the semiconductor device further includes between the substrate and the EUV mask or as part of the EUV mask protective structure, at least one layer selected from a sacrificial layer, an insulation layer, a passivation layer, a low k layer, a metal-containing layer and a barrier layer. In another aspect, the EUV mask protecting structure includes at least one layer selected from a sacrificial layer, an insulation layer, a passivation layer, a graphene layer, an EUV transmission layer, a linking layer and a heat dissipation layer.

In another aspect, the disclosed and claimed subject matter relates to a system that includes at least one of the compositions of the disclosed and claimed subject matter in conjunction with the above-described semiconductor devices, including a metal-containing EUV mask-protecting structure.

The compositions, methods and systems of the disclosed and claimed subject matter provide high removability rates and good compatibility with materials of the semiconductor device. For example, the metal etchant composition has higher than 300 Å/min Ni etch rate and good compatibility with Si₃N₄ and SiO₂. Additionally, the compositions, methods and systems of the disclosed and claimed subject matter provide high solubility for metal oxides.

### DETAILED DESCRIPTION

All references, including publications, patent applications, and patents, cited herein are hereby incorporated by reference to the same extent as if each reference were individually and specifically indicated to be incorporated by reference and were set forth in its entirety herein, including WO2017183941A1 and U.S. Pat. No. 8,535,545 and others.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. The use of the term “comprising” or “including” in the specification and the claims includes the narrower language of “consisting essentially of” and “consisting of”

In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the etching composition can contain 2% by weight or less of impurities. In another embodiment, the etching composition can contain 1% by weight or less than of impurities. In a further embodiment, the etching composition can contain 0.05% by weight or less than of impurities. In other such embodiments, the ingredients can form at least 90 wt %, more preferably at least 95 wt %, more preferably at least 99 wt %, more preferably at least 99.5 wt %, most preferably at least 99.9 wt %, and can include other ingredients that do not material affect the performance of the etching compositions. Otherwise, if no significant non-essential impurity component is present, it is understood that the combination of all essential constituent components will essentially add up to 100 weight %.

Embodiments of the disclosed and claimed subject matter are described herein, including the best mode known to the inventors for carrying out the disclosed and claimed subject matter. Variations of those embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, the disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

It will be understood that the term “silicon” as deposited as a material on a microelectronic device will include polysilicon.

For ease of reference, “microelectronic device” or “semiconductor device” corresponds to semiconductor wafers having integrated circuits, memory, and other electronic structures fabricated thereon, and flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” or “semiconductor device” is not meant to be limiting in any way and includes any substrate that will eventually become a microelectronic device or microelectronic assembly.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 0.001 wt. %. “Substantially free” also includes 0.000 wt. %. The term “free of” means 0.000 wt. %.

As used herein, “about” or “approximately” are intended to correspond to within ±5% of the stated value.

In all such compositions, wherein specific components of the composition are discussed in reference to weight percentage (or “weight %”) ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all percentages of the components are weight percentages and are based on the total weight of the composition, that is, 100%. Any reference to “one or more” or “at least one” includes “two or more” and “three or more” and so on.

Where applicable, all weight percents unless otherwise indicated are “neat” meaning that they do not include the aqueous solution in which they are present when added to the composition. As used herein, for example, “neat” refers to the weight % amount of an undiluted acid or other material (i.e., the inclusion 100 g of 85% phosphoric acid constitutes 85 g of the acid and 15 grams of diluent).

Moreover, when referring to the compositions described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the formulation can contain 2% by weight or less of impurities. In another embodiment, the formulation can contain 1% by weight or less than of impurities. In a further embodiment, the formulation can contain 0.05% by weight or less than of impurities. In other such embodiments, the constituents can form at least 90 wt %, more preferably at least 95 wt %, more preferably at least 99 wt %, more preferably at least 99.5 wt %, most preferably at least 99.9 wt %, and can include other ingredients that do not material affect the performance of the wet etchant. Otherwise, if no significant non-essential impurity component is present, it is understood that the composition of all essential constituent components will essentially add up to 100 weight %.

The headings employed herein are not intended to be limiting; rather, they are included for organizational purposes only.

Compositions

As noted above, one aspect of the disclosed and claimed subject matter pertains to a metal etching composition and method that has high removability rates. The etching compositions also provide good compatibility with silicon nitrate (Si₃N₄) and silicon oxide (SiO₂) and other materials on the semiconductor substrate.

In one embodiment, the disclosed and claimed subject matter relates to a composition that includes:
(i) water;
(ii) one or more oxidizing agents; and
(iii) one or more acids
   wherein the composition is designed for removing a metal-containing layer in a EUV mask protective structure that includes only the metal-containing layer or that further includes one or more additional layers of materials. Thus, in some embodiments the composition for removing a metal-containing layer can includes, can consist essentially of, or alternatively can consist of water; at least one oxidizer; and the at least one acid as describe below.

In other embodiments, the composition further includes (iv) a halogen ion source. Thus, as described below in more detail, in some embodiments the composition for removing a metal-containing layer can includes, can consist essentially of, or alternatively can consist of (i) water; (ii) one or more oxidizing agents, (iii) one or more acids and (iv) a halogen ion source.

In other embodiment, the composition further includes (v) a chelating agent. Thus, as described below in more detail, in some embodiments the composition for removing a metal-containing layer can includes, can consist essentially of, or alternatively can consist of (i) water; (ii) one or more oxidizing agents, (iii) one or more acids and (v) a chelating agent.

In other embodiment, the composition further includes (iv) a halogen ion source and (v) a chelating agent. Thus, as described below in more detail, in some embodiments the composition for removing a metal-containing layer can includes, can consist essentially of, or alternatively can consist of (i) water; (ii) one or more oxidizing agents, (iii) one or more acids, (iv) a halogen ion source and (v) a chelating agent.

In one embodiment, the composition includes (i) water; (ii) one or more oxidizing agents and (iii) one or more acids in varying concentrations.

In a further embodiment, the composition includes (i) water; (ii) one or more oxidizing agents, (iii) one or more acids and (iv) a halogen ion source in varying concentrations.

In a further embodiment, the composition includes (i) water; (ii) one or more oxidizing agents, (iii) one or more acids and (v) a chelating agent in varying concentrations.

In a further embodiment, the composition includes (i) water; (ii) one or more oxidizing agents, (iii) one or more acids, (iv) a halogen ion source and (v) a chelating agent in varying concentrations.

In one embodiment, the composition consists essentially of (i) water; (ii) one or more oxidizing agents and (iii) one or more acids in varying concentrations. In such an embodiment, the combined amounts of (i), (ii) and (iii) do not equal 100% by weight, and can include other ingredients (e.g., additional solvent(s), common additives and/or impurities) that do not materially change the effectiveness of the composition.

In a further embodiment, the composition consists essentially of (i) water; (ii) one or more oxidizing agents, (iii) one or more acids and (iv) a halogen ion source in varying concentrations. In such an embodiment, the combined amounts of (i), (ii), (iii) and (iv) do not equal 100% by weight, and can include other ingredients (e.g., additional solvent(s), common additives and/or impurities) that do not materially change the effectiveness of the composition.

In a further embodiment, the composition consists essentially of (i) water; (ii) one or more oxidizing agents, (iii) one or more acids and (v) a chelating agent in varying concentrations. In such an embodiment, the combined amounts of (i), (ii), (iii) and (v) do not equal 100% by weight, and can include other ingredients (e.g., additional solvent(s), common additives and/or impurities) that do not materially change the effectiveness of the composition.

In a further embodiment, the composition consists essentially of (i) water; (ii) one or more oxidizing agents, (iii) one or more acids, (iv) a halogen ion source and (v) a chelating agent in varying concentrations. In such an embodiment, the combined amounts of (i), (ii), (iii), (iv) and (v) do not equal 100% by weight, and can include other ingredients (e.g., additional solvent(s), common additives and/or impurities) that do not materially change the effectiveness of the composition.

In a further embodiment, the composition consists of (i) water; (ii) one or more oxidizing agents and (iii) one or more acids in varying concentrations. In such an embodiment, the combined amounts of (i), (ii) and (iii) equal approximately 100% by weight but may include other small and/or trace amounts of impurities that are present in such small quantities that they do not materially change the effectiveness of the composition. For example, in one such embodiment, the composition can contain 2% by weight or less of impurities. In another embodiment, the composition can contain 1% by weight or less than of impurities. In a further embodiment, the composition can contain 0.05% by weight or less than of impurities.

In a further embodiment, the composition consists of (i) water; (ii) one or more oxidizing agents, (iii) one or more acids and (iv) a halogen ion source in varying concentrations. In such an embodiment, the combined amounts of (i), (ii), (iii) and (iv) equal approximately 100% by weight but may include other small and/or trace amounts of impurities that are present in such small quantities that they do not materially change the effectiveness of the composition. For example, in one such embodiment, the composition can contain 2% by weight or less of impurities. In another embodiment, the composition can contain 1% by weight or less than of impurities. In a further embodiment, the composition can contain 0.05% by weight or less than of impurities.

In a further embodiment, the composition consists of (i) water; (ii) one or more oxidizing agents, (iii) one or more acids and (v) a chelating agent in varying concentrations. In such an embodiment, the combined amounts of (i), (ii), (iii) and (v) equal approximately 100% by weight but may include other small and/or trace amounts of impurities that are present in such small quantities that they do not materially change the effectiveness of the composition. For example, in one such embodiment, the composition can contain 2% by weight or less of impurities. In another embodiment, the composition can contain 1% by weight or less than of impurities. In a further embodiment, the composition can contain 0.05% by weight or less than of impurities.

In a further embodiment, the composition consists of (i) water; (ii) one or more oxidizing agents, (iii) one or more acids, (iv) a halogen ion source and (v) a chelating agent in varying concentrations. In such an embodiment, the combined amounts of (i), (ii), (iii), (iv) and (v) equal approximately 100% by weight but may include other small and/or trace amounts of impurities that are present in such small quantities that they do not materially change the effectiveness of the composition. For example, in one such embodiment, the composition can contain 2% by weight or less of impurities. In another embodiment, the composition can contain 1% by weight or less than of impurities. In a further embodiment, the composition can contain 0.05% by weight or less than of impurities.

(i) Water

The etching compositions of the disclosed and claimed subject matter are aqueous-based and, thus, include water. In the disclosed and claimed subject matter, water functions in various ways such as, for example, to dissolve one or more solid components of the residue, as a carrier of the components, as an aid in the removal of the metal, for example, Ni, as a viscosity modifier of the composition, and as a diluent. Preferably, the water employed in the etching composition is de-ionized (DI) water. Water may be added directly to the composition or water may be added to the composition via components that are added to the etching composition in aqueous solutions. The portion of the water added to the etching composition via aqueous components is reported as part of the wt % water in the composition.

Water is included in an amount in a range having start and end points selected from the following list of weight percents: 30, 33, 35, 38, 40, 42, 45, 50, 55, 60, 63, 65, 67, 68, 70, 72, 75, 77, 80, 83, 85, 87, 90, 92, 94 and 96; for examples, from about 30% to about 94% by wt., or from about 40% to about 90% by wt., or about 45% to about 70% by wt., or from about 45% to about 85% by wt., or from about 35% to about 75% by wt., or from about 40% to about 60% by wt., or from about 60% to about 92% by wt. of water. Still other preferred embodiments of the disclosed and claimed subject matter include water in an amount to achieve the desired weight percent of the other ingredients.

(ii) Oxidizing Agent

The etching composition of the disclosed and claimed subject matter includes at least one oxidizing agent. As used herein, the term “oxidizing agents” correspond to compounds that oxidize exposed metal(s) resulting in corrosion of the metal or oxide formation on the metal. In the etching composition, the oxidizing agents are used to oxidize any metals present to metal oxide and make it/them soluble in the etching solution. Oxidizing agents include but are not limited to hydrogen peroxide; other percompounds such as salts and acids containing peroxomonosulfate, perborate, perchlorate, perchloric acid, peracetate anions, sulfuric acid periodate, persulfate, permanganate, and other compounds such as chromate, dichromate, benzoquinones, nitric acid and amine-N-oxides. Specific examples of useful oxidizing agents include nitric acid, ammonium persulfate (APS), 2,5-Dihydroxy-1,4-benzoquinone, nitrosylsulfuric acid, and pyridine N-oxide, 4-Methylmorpholine N-oxide. Acids are considered oxidizing agents when they have a reduction potential greater than 0 and will be referred to as “oxidizing agents” not acids.

The oxidizing agent(s) are included in an amount in a range having start and end points selected from the following list of weight percents: 0.001, 0.003, 0.005, 0.008, 0.01, 0.03, 0.05, 0.07, 0.09, 0.1, 0.3, 0.5, 0.8, 1, 1.3, 1.5, 1.8, 2.0, 2.3, 2.5, 2.8, 3, 3.3, 3.5, 3.7, 4, 4.3, 4.5, 4.8, 5, 5.3, 5.5, 5.8, 6.0, 6.3, 6.5, 6.8, 7, 7.3, 7.5, 7.7, 8, 8.3, 8.5, 8.8, 9, 9.3, 9.5, 9.7, 10 for examples, from about 0.001% to about 10% by wt., or from about 0.005% to about 5% by wt., or about 0.008% to about 3% by wt., or from about 0.1% to about 7% by wt., or from about 0.1% to about 6% by wt. of the oxidizing agent. Still other preferred embodiments of the disclosed and claimed subject matter include the oxidizing agent(s) in different amounts depending upon the strength of the selected oxidizing agent and the desired results. Note that if the oxidizing agent is added to the composition in an aqueous solution, the water is excluded from the wt %. Therefore if 1 gram of a 60% nitric acid aqueous solution is added to the composition, 0.6 grams of nitric acid and 0.4 grams of water are added to the solution (i.e., the 0.4 grams water is added to and reflected in the (total) amount of water in the section above.)

(iii) Acids

The Ni etching composition of the disclosed and claimed subject matter includes one or more inorganic and/or organic acids. Useful acids include sulfuric acid, hydrochloric acid, alkyl sulfonic acid, such as, methane sulfonic acid (MSA), alkyl benzyl sulfonic acid, such as, 4-methylbenzenesulfonic acid, hydrobromic acid, citric acid, malonic acid, hydrofluoric acid, acetic acid, phosphoric acid and hydroiodic acid. In preferred embodiments, two or more acids are present.

The one or more acids include an amount in a range having start and end points selected from the following list of weight percents: 10, 12, 15, 17, 20, 23, 25, 27, 30, 33, 35, 38, 40, 42, 45, 50, 55, 60, 63, 65, 67, 68, 70, 73, 75, 77 and 80, for examples, from about 10% to about 80% by wt., or from about 20% to about 70% by wt., or about 35% to about 75% by wt., or from about 40% to about 65% by wt., or from about 30% to about 70% by wt., of one or more acids. Still other preferred embodiments of the disclosed and claimed subject matter include the one or more acids in different amounts depending upon the strength of the selected acid(s) and the desired results. Note that if the one or more acids are added to the composition in an aqueous solution, the water is excluded from the wt %. (i.e., therefore if 10 grams of a 35% HCl acid aqueous solution is added to the composition, 3.5 grams of HCl and 6.5 grams of water are added to the solution).

Some compositions have two or more acids present therein. In some embodiments, a first acid is present in the composition at 2× or more, or 5× or more, 10× or more, or 20× or more, or 25× or more the amount that the second acid present in the composition.

(iv) Halogen Ion Source

The compositions of the disclosed and claimed subject matter may also include a halogen ion source. The halogen ion source, such as, a chloride ion, bromide ion, iodide ion, fluoride ion source, for examples, hydrobromic acid (HBr), hydroiodic acid (HI), hydrogen chloride, HF, HCl, ammonium chloride, ammonium bromide, ammonium fluoride and ammonium iodide. For example, HCl, HBr, HF and HI can be used as the acid or as at least one acid present in the etching composition for the benefit of adding halogen ions to the solution. Additionally, or alternatively, NH₄Cl, NH₄I, NH₄F and NH₄Br may also be added to the etching composition. The one or more halogen ion sources include an amount in a range having start and end points selected from the following list of weight percents: 0.01, 0.05, 0.07, 0.1, 0.3, 0.5, 0.7, 1, 1.3, 1.5, 1.7, 2, 3, 5, 7, 10, 12 and 15, for examples, from about 0.01% to about 15% by wt., or from about 0.1% to about 10% by wt., or about 0.05% to about 12% by wt., or from about 0.01% to about 7% by wt., or from about 0.1% to about 5% by wt. of one or more halogen ion sources.

If an acid, for example HCl, HBr, HF or HI is present, it is included in the amounts reported for the acid in the section above (and not included in the amount of the metal chelating agent).

In some embodiments, the compositions disclosed herein are formulated to be substantially free or free of inorganic bases and/or quaternary ammonium fluorides and/or quaternary ammonium hydroxides, for examples the composition may be free of one or more of the following: fluorine-containing compounds, metal hydroxides, tetramethylammonium fluoride, tetraethylammonium fluoride, methyltriethylammonium fluoride, and tetrabutylammonium fluoride, tetramethylammonium hydroxide, tetraethylammonium hydroxide, methyltriethylammonium hydroxide, and/or tetrabutylammonium hydroxide, abrasives, organic solvents, surfactants, metal containing compounds. The compositions may be free of alkanolamines or primary, secondary or tertiary amines or organic solvents or organic acids.

(v) Chelator

The compositions of the disclosed and claimed subject matter may also include a metal chelating agent. One function of chelators is to increase the dissolving rates of metals or metal containing compounds by forming complexes between chelators and metal ions. It is also believed that the metal chelating agent stabilizes the composition by complexing with trace metals that may accumulate in the composition during use of the composition, thereby preventing the trace metals from decomposing the oxidizer of the composition. For example, free trace metal cations, such as copper ions, catalyze the decomposition of hydrogen peroxide into oxygen and water, which will accelerate the reduction of etching and cleaning performance of the composition over time.

Examples of suitable chelating agents include, but are not limited to glycine, serine, proline, leucine, alanine, asparagine, aspartic acid, glutamine, glutamic acid, valine, lysine, cystine, nitrilotriacetic acid (NTA), iminodiacetic acid (IDA), ethylenediaminetetraacetic acid (EDTA), (1,2-cyclohexylenedinitrilo)tetraacetic acid (CDTA), uric acid, tetraglyme, diethylenetriamine pentaacetic acid (DTPA), propylenediamine-N,N,N′,N′-tetraacetic acid, ethylendiamine disuccinic acid (EDDS), sulfanilamide, 1,4,7,10-tetraazacyclododecane-1,4,7,10 tetraacetic acid; ethylene glycol tetraacetic acid (EGTA); 1,2-bis(o-aminophenoxy)ethane-N,N,N′,N′-tetraacetic acid; N-2-bis(carboxymethyl)aminoethyl-N-(2-hydroxy ethyl)glycine (HEDTA); and ethylenediamine-N,N′-bis(2-hydroxyphenylacetic acid) (EDDHA), 1,3-diaminopropane-N,N,N′,N′-tetraacetic acid, gluconic acid, N,N,N′,N′-ethylenediaminetetrakis(methylenephosphonic acid) (EDTMP), diethylenetriamine penta(methylene phosphonic acid) (ETDMP), nitrilotris(methylene)triphosphonic acid (ATMP), tartaric acid, 3,4-dihydroxybenzoic acid, Salicylic acid, 8-Hydroxyquinoline (8-HQ), etidronic acid (HEDP), 1,3-propanediamine-N,N,N′,N′-tetraacetic acid, triethylenetetramine hexaacetic acid (TTHA), picolinic acid and combinations thereof.

If present, the compositions include includes 0-10 wt percent, more preferably 50 ppm-5 wt percent, and most preferably 100 ppm-3 wt percent of the chelator. In alternative embodiments, the optional chelator may be present in the composition in an amount within a weight percent range having any of the following start and end points: 0, 0.000001, 0.000005, 0.00001, 0.00005, 0.0001, 0.0005, 0.001, 0.005, 0.01, 0.05, 0.1, 0.5, 1, 2, 3, 4, 5, 6, 7, 8, 9 and 10. For examples the composition may include from 0.0001 to 8 wt percent, or from 0.001 to about 5 wt percent or from 0.01 to 2 wt percent of the chelator.

Exemplary Formulations

Non-limiting embodiment of the disclosed and claimed cleaning formulation are described. Working examples are also shown below.

In one embodiment of the cleaning composition, the one or more oxidizing agents include nitric acid. In a further aspect of this embodiment, the one or more oxidizing agents consists essentially of nitric acid. In a further aspect of this embodiment, the one or more oxidizing agents consists of nitric acid. In a further aspect of this embodiment, the one or more oxidizing agents includes between approximately 0.1 wt % and approximately 1.0 wt % of neat nitric acid. In a further aspect of this embodiment, the one or more oxidizing agents consists essentially of approximately 0.1 wt % and approximately 1.0 wt % of neat nitric acid. In a further aspect of this embodiment, the one or more oxidizing agents consists of approximately 0.1 wt % and approximately 1.0 wt % of neat nitric acid. In a further aspect of this embodiment, the one or more oxidizing agents includes approximately 0.9 wt % of neat nitric acid. In a further aspect of this embodiment, the one or more oxidizing agents consists essentially of approximately 0.9 wt % of neat nitric acid. In a further aspect of this embodiment, the one or more oxidizing agents consists of approximately 0.9 wt % of neat nitric acid. In a further aspect of this embodiment, the one or more oxidizing agents includes approximately 0.6 wt % of neat nitric acid. In a further aspect of this embodiment, the one or more oxidizing agents consists essentially of approximately 0.6 wt % of neat nitric acid. In a further aspect of this embodiment, the one or more oxidizing agents consists of approximately 0.6 wt % of neat nitric acid.

In another embodiment of the cleaning composition, the one or more oxidizing agents includes 2,5-dihydroxy-1,4-benzoquinone. In a further aspect of this embodiment, the one or more oxidizing agents consists essentially of 2,5-dihydroxy-1,4-benzoquinone. In a further aspect of this embodiment, the one or more oxidizing agents consists of 2,5-dihydroxy-1,4-benzoquinone. In a further aspect of this embodiment, the one or more oxidizing agents includes approximately 0.01 wt % of 2,5-dihydroxy-1,4-benzoquinone. In a further aspect of this embodiment, the one or more oxidizing agents consists essentially of approximately 0.01 wt % of 2,5-dihydroxy-1,4-benzoquinone. In a further aspect of this embodiment, the one or more oxidizing agents consists of approximately 0.01 wt % of 2,5-dihydroxy-1,4-benzoquinone.

In another embodiment of the cleaning composition, the one or more oxidizing agents includes ammonium persulfate. In a further aspect of this embodiment, the one or more oxidizing agents consists essentially of and ammonium persulfate. In a further aspect of this embodiment, the one or more oxidizing agents consists of ammonium persulfate. In a further aspect of this embodiment, the one or more oxidizing agents comprises approximately 1.0 wt % of ammonium persulfate. In a further aspect of this embodiment, the one or more oxidizing agents consists essentially of approximately 1.0 wt % of ammonium persulfate. In a further aspect of this embodiment, the one or more oxidizing agents consists of approximately 1.0 wt % of ammonium persulfate.

In another embodiment of the cleaning composition, the total wt % of neat acid in the composition is approximately 15 wt % to approximately 50 wt %. In a further aspect of this embodiment, the total wt % of neat acid in the composition is approximately 30 wt % to approximately 45 wt %. In a further aspect of this embodiment, the total wt % of neat acid in the composition is approximately 35 wt % to approximately 45 wt %. In a further aspect of this embodiment, the total wt % of neat acid in the composition is approximately 30 wt % to approximately 40 wt %. In a further aspect of this embodiment, the total wt % of neat acid in the composition is approximately 35 wt % to approximately 40 wt %. In a further aspect of this embodiment, the total wt % of neat acid in the composition is approximately 40 wt % to approximately 45 wt %.

In another embodiment of the cleaning composition, the one or more acids includes sulfuric acid. In a further aspect of this embodiment, the one or more acids consists essentially of sulfuric acid. In a further aspect of this embodiment, the one or more acids consists of sulfuric acid. In a further aspect of this embodiment, the one or more acids comprises approximately 38.8 wt % of neat sulfuric acid. In a further aspect of this embodiment, the one or more acids consists essentially of approximately 38.8 wt % of neat sulfuric acid. In a further aspect of this embodiment, the one or more acids consists of approximately 38.8 wt % of neat sulfuric acid.

In another embodiment of the cleaning composition, the one or more acids includes hydrochloric acid. In a further aspect of this embodiment, the one or more acids consists essentially of hydrochloric acid. In a further aspect of this embodiment, the one or more acids consists of hydrochloric acid. In a further aspect of this embodiment, the one or more acids includes approximately 4.725 wt % of neat hydrochloric acid. In a further aspect of this embodiment, the one or more acids consists essentially of approximately 4.725 wt % of hydrochloric acid. In a further aspect of this embodiment, the one or more acids consists of approximately 4.725 wt % of hydrochloric acid. In a further aspect of this embodiment, the one or more acids includes approximately 3.5 wt % of neat hydrochloric acid. In a further aspect of this embodiment, the one or more acids consists essentially of approximately 3.5 wt % of hydrochloric acid. In a further aspect of this embodiment, the one or more acids consists of approximately 3.5 wt % of hydrochloric acid.

In another embodiment of the cleaning composition, the one or more acids includes sulfuric acid and hydrochloric acid. In a further aspect of this embodiment, the one or more acids consists essentially of sulfuric acid and hydrochloric acid. In a further aspect of this embodiment, the one or more acids consists of sulfuric acid and hydrochloric acid. In a further aspect of this embodiment, the one or more acids includes approximately 38.8 wt % of neat sulfuric acid and of approximately 4.725 wt % of neat hydrochloric acid. In a further aspect of this embodiment, the one or more acids consists essentially of approximately 38.8 wt % of neat sulfuric acid and of approximately 4.725 wt % of neat hydrochloric acid. In a further aspect of this embodiment, the one or more acids consists of approximately 38.8 wt % of neat sulfuric acid and of approximately 4.725 wt % of neat hydrochloric acid. In a further aspect of this embodiment, the one or more acids includes approximately 38.8 wt % of neat sulfuric acid and of approximately 3.5 wt % of neat hydrochloric acid. In a further aspect of this embodiment, the one or more acids consists essentially of approximately 38.8 wt % of neat sulfuric acid and of approximately 3.5 wt % of neat hydrochloric acid. In a further aspect of this embodiment, the one or more acids consists of approximately 38.8 wt % of neat sulfuric acid and of approximately 3.5 wt % of neat hydrochloric acid.

In another embodiment, the cleaning composition includes water, sulfuric acid and nitric acid. In a further aspect of this embodiment, the cleaning composition consists essentially of water, sulfuric acid and nitric acid. In a further aspect of this embodiment, the cleaning composition consists of water, sulfuric acid and nitric acid. In a further aspect of this embodiment, the cleaning composition includes water, approximately 33.5 wt % to approximately 50 wt % of neat sulfuric acid and approximately 0.9 wt % of neat nitric acid. In a further aspect of this embodiment, the cleaning composition consists essentially of water, approximately 33.5 wt % to approximately 50 wt % of neat sulfuric acid and approximately 0.9 wt % of neat nitric acid. In a further aspect of this embodiment, the cleaning composition consists of water, approximately 33.5 wt % to approximately 50 wt % of neat sulfuric acid and approximately 0.9 wt % of neat nitric acid.

In another embodiment, the cleaning composition includes water, hydrochloric acid and nitric acid. In a further aspect of this embodiment, the composition consists essentially of water, hydrochloric acid and nitric acid. In a further aspect of this embodiment, the composition consists of water, hydrochloric acid and nitric acid. In a further aspect of this embodiment, the composition includes water, approximately 3.0 wt % to approximately 5.0 wt % of neat hydrochloric acid and approximately 0.6 wt % to approximately 0.9 wt % of neat nitric acid. In a further aspect of this embodiment, the composition consists essentially of water, approximately 3.0 wt % to approximately 5.0 wt % of neat hydrochloric acid and approximately 0.6 wt % to approximately 0.9 wt % of neat nitric acid. In a further aspect of this embodiment, the composition consists of water, approximately 3.0 wt % to approximately 5.0 wt % of neat hydrochloric acid and approximately 0.6 wt % to approximately 0.9 wt % of neat nitric acid.

In another embodiment, the composition includes water, hydrochloric acid, nitric acid and methane sulfonic acid. In a further aspect of this embodiment, the composition consists essentially of water, hydrochloric acid, nitric acid and methane sulfonic acid. In a further aspect of this embodiment, the composition consists of water, hydrochloric acid, nitric acid and methane sulfonic acid. In a further aspect of this embodiment, the composition includes water, approximately 3.0 wt % to approximately 5.0 wt % of neat hydrochloric acid, approximately 0.6 wt % to approximately 0.9 wt % of neat nitric acid and approximately 40 wt % of methane sulfonic acid. In a further aspect of this embodiment, the composition consists essentially of water, approximately 3.0 wt % to approximately 5.0 wt % of neat hydrochloric acid, approximately 0.6 wt % to approximately 0.9 wt % of neat nitric acid and approximately 40 wt % of methane sulfonic acid. In a further aspect of this embodiment, the composition consists of water, approximately 3.0 wt % to approximately 5.0 wt % of neat hydrochloric acid, approximately 0.6 wt % to approximately 0.9 wt % of neat nitric acid and approximately 40 wt % of methane sulfonic acid.

In another embodiment, the composition includes water, hydrochloric acid, nitric acid, methane sulfonic acid and 2,5-dihydroxy-1,4-benzoquinone. In a further aspect of this embodiment, the composition consists essentially of water, hydrochloric acid, nitric acid, methane sulfonic acid and 2,5-dihydroxy-1,4-benzoquinone. In a further aspect of this embodiment, the composition consists of water, hydrochloric acid, nitric acid, methane sulfonic acid and 2,5-dihydroxy-1,4-benzoquinone. In a further aspect of this embodiment, the composition includes water, approximately 3.0 wt % to approximately 5.0 wt % of neat hydrochloric acid, approximately 0.6 wt % to approximately 0.9 wt % of neat nitric acid, approximately 40 wt % of methane sulfonic acid and 2,5-dihydroxy-1,4-benzoquinone. In a further aspect of this embodiment, the composition consists essentially of water, approximately 3.0 wt % to approximately 5.0 wt % of neat hydrochloric acid, approximately 0.6 wt % to approximately 0.9 wt % of neat nitric acid, approximately 40 wt % of methane sulfonic acid and 2,5-dihydroxy-1,4-benzoquinone. In a further aspect of this embodiment, the composition consists of water, approximately 3.0 wt % to approximately 5.0 wt % of neat hydrochloric acid, approximately 0.6 wt % to approximately 0.9 wt % of neat nitric acid, approximately 40 wt % of methane sulfonic acid and 2,5-dihydroxy-1,4-benzoquinone.

In another embodiment, the composition includes water, hydrochloric acid, methane sulfonic acid and 2,5-dihydroxy-1,4-benzoquinone. In a further aspect of this embodiment, the composition consists essentially of water, hydrochloric acid, methane sulfonic acid and 2,5-dihydroxy-1,4-benzoquinone. In a further aspect of this embodiment, the composition consists of water, hydrochloric acid, methane sulfonic acid and 2,5-dihydroxy-1,4-benzoquinone. In a further aspect of this embodiment, the composition includes water, approximately 3.0 wt % to approximately 5.0 wt % of neat hydrochloric acid, approximately 40 wt % of methane sulfonic acid and 2,5-dihydroxy-1,4-benzoquinone. In a further aspect of this embodiment, the composition consists essentially of water, approximately 3.0 wt % to approximately 5.0 wt % of neat hydrochloric acid, approximately 40 wt % of methane sulfonic acid and 2,5-dihydroxy-1,4-benzoquinone. In a further aspect of this embodiment, the composition consists of water, approximately 3.0 wt % to approximately 5.0 wt % of neat hydrochloric acid, approximately 40 wt % of methane sulfonic acid and 2,5-dihydroxy-1,4-benzoquinone.

In another embodiment, the composition includes water, sulfuric acid, hydrochloric acid and nitric acid. In a further aspect of this embodiment, the composition consists essentially of water, sulfuric acid, hydrochloric acid and nitric acid. In a further aspect of this embodiment, the composition consists of water, sulfuric acid, hydrochloric acid and nitric acid. In a further aspect of this embodiment, the composition includes water and approximately 40 wt % to approximately 45 wt % combined of neat sulfuric acid, neat hydrochloric acid and neat nitric acid. In a further aspect of this embodiment, the composition consists essentially of water and approximately 40 wt % to approximately 45 wt % combined of neat sulfuric acid, neat hydrochloric acid and neat nitric acid. In a further aspect of this embodiment, the composition consists of water and approximately 40 wt % to approximately 45 wt % combined of neat sulfuric acid, neat hydrochloric acid and neat nitric acid. In a further aspect of this embodiment, the composition includes water and approximately 43 wt % to approximately 45 wt % combined of neat sulfuric acid, neat hydrochloric acid and neat nitric acid. In a further aspect of this embodiment, the composition consists essentially of water and approximately 43 wt % to approximately 45 wt % combined of neat sulfuric acid, neat hydrochloric acid and neat nitric acid. In a further aspect of this embodiment, the composition consists of water and approximately 43 wt % to approximately 45 wt % combined of neat sulfuric acid, neat hydrochloric acid and neat nitric acid. In a further aspect of this embodiment, the composition includes water, approximately 38.8 wt % of neat sulfuric acid, approximately 4.725 wt % of neat hydrochloric acid and approximately 0.6 wt % of neat nitric acid. In a further aspect of this embodiment, the composition consists essentially of water, approximately 38.8 wt % of neat sulfuric acid, approximately 4.725 wt % of neat hydrochloric acid and approximately 0.6 wt % of neat nitric acid. In a further aspect of this embodiment, the composition consists of water, approximately 38.8 wt % of neat sulfuric acid, approximately 4.725 wt % of neat hydrochloric acid and approximately 0.6 wt % of neat nitric acid. In a further aspect of this embodiment, the composition includes water, approximately 38.8 wt % of neat sulfuric acid, approximately 4.725 wt % of neat hydrochloric acid and approximately 0.9 wt % of neat nitric acid. In a further aspect of this embodiment, the composition consists essentially of water, approximately 38.8 wt % of neat sulfuric acid, approximately 4.725 wt % of neat hydrochloric acid and approximately 0.9 wt % of neat nitric acid. In a further aspect of this embodiment, the composition consists of water, approximately 38.8 wt % of neat sulfuric acid, approximately 4.725 wt % of neat hydrochloric acid and approximately 0.9 wt % of neat nitric acid. In a further aspect of this embodiment, the composition includes water, approximately 38.8 wt % of neat sulfuric acid, approximately 3.5 wt % of neat hydrochloric acid and approximately 0.6 wt % of neat nitric acid. In a further aspect of this embodiment, the composition consists essentially of water, approximately 38.8 wt % of neat sulfuric acid, approximately 3.5 wt % of neat hydrochloric acid and approximately 0.6 wt % of neat nitric acid. In a further aspect of this embodiment, the composition consists of water, approximately 38.8 wt % of neat sulfuric acid, approximately 3.5 wt % of neat hydrochloric acid and approximately 0.6 wt % of neat nitric acid. In a further aspect of this embodiment, the composition includes water, approximately 38.8 wt % of neat sulfuric acid, approximately 3.5 wt % of neat hydrochloric acid and approximately 0.9 wt % of neat nitric acid. In a further aspect of this embodiment, the composition consists essentially of water, approximately 38.8 wt % of neat sulfuric acid, approximately 3.5 wt % of neat hydrochloric acid and approximately 0.9 wt % of neat nitric acid. In a further aspect of this embodiment, the composition consists of water, approximately 38.8 wt % of neat sulfuric acid, approximately 3.5 wt % of neat hydrochloric acid and approximately 0.9 wt % of neat nitric acid.

In another embodiment, the composition includes water, sulfuric acid, hydrochloric acid, nitric acid and ammonium chloride. In a further aspect of this embodiment, the composition consists essentially of water, sulfuric acid, hydrochloric acid, nitric acid and ammonium chloride. In a further aspect of this embodiment, the composition consists of water sulfuric acid, hydrochloric acid, nitric acid and ammonium chloride. In a further aspect of this embodiment, the composition includes water, approximately 38.8 wt % of neat sulfuric acid, approximately 4.725 wt % of neat hydrochloric acid, approximately 0.6 wt % of neat nitric acid and ammonium chloride. In a further aspect of this embodiment, the composition consists essentially of water, approximately 38.8 wt % of neat sulfuric acid, approximately 4.725 wt % of neat hydrochloric acid, approximately 0.6 wt % of neat nitric acid and ammonium chloride. In a further aspect of this embodiment, the composition consists of water, approximately 38.8 wt % of neat sulfuric acid, approximately 4.725 wt % of neat hydrochloric acid, approximately 0.6 wt % of neat nitric acid and ammonium chloride. In a further aspect of this embodiment, the composition includes water, approximately 38.8 wt % of neat sulfuric acid, approximately 4.725 wt % of neat hydrochloric acid, approximately 0.9 wt % of neat nitric acid and ammonium chloride. In a further aspect of this embodiment, the composition consists essentially of water, approximately 38.8 wt % of neat sulfuric acid, approximately 4.725 wt % of neat hydrochloric acid, approximately 0.9 wt % of neat nitric acid and ammonium chloride. In a further aspect of this embodiment, the composition consists of water, approximately 38.8 wt % of neat sulfuric acid, approximately 4.725 wt % of neat hydrochloric acid, approximately 0.9 wt % of neat nitric acid and ammonium chloride.

In another embodiment of the cleaning composition, the one or more halogen ion source includes one or more of hydrobromic acid, hydroiodic acid, hydrogen chloride, hydrofluoric acid, hydrochloric acid, ammonium chloride, ammonium bromide, ammonium fluoride and ammonium iodide. In a further aspect of this embodiment, the one or more halogen ion source consists essentially of one or more of hydrobromic acid, hydroiodic acid, hydrogen chloride, hydrofluoric acid, hydrochloric acid, ammonium chloride, ammonium bromide, ammonium fluoride and ammonium iodide. In a further aspect of this embodiment, the one or more halogen ion source consists of one or more of hydrobromic acid, hydroiodic acid, hydrogen chloride, hydrofluoric acid, hydrochloric acid, ammonium chloride, ammonium bromide, ammonium fluoride and ammonium iodide. In a further aspect of this embodiment, the one or more halogen ion source includes approximately 2 wt % of ammonium chloride. In a further aspect of this embodiment, the one or more halogen ion source consists essentially of approximately 2 wt % ammonium chloride. In a further aspect of this embodiment, the one or more halogen ion source consists of approximately 2 wt % ammonium chloride.

Performance

The disclosed and claimed cleaning compositions have high Ni etch rates (at approximately 30° C.).

In one embodiment, the disclosed and claimed cleaning compositions have a Ni etch rate of approximately 200 to approximately 700. In a further aspect of this embodiment, the compositions have a Ni etch rate of approximately 300 to approximately 700. In a further aspect of this embodiment, the compositions have a Ni etch rate of approximately 400 to approximately 700. In a further aspect of this embodiment, the compositions have a Ni etch rate of approximately 500 to approximately 700. In a further aspect of this embodiment, the compositions have a Ni etch rate of approximately 600 to approximately 700. In a further aspect of this embodiment, the compositions have a Ni etch rate of approximately 200 or greater. In a further aspect of this embodiment, the compositions have a Ni etch rate of approximately 300 or greater. In a further aspect of this embodiment, the compositions have a Ni etch rate of approximately 400 or greater. In a further aspect of this embodiment, the compositions have a Ni etch rate of approximately 500 or greater. In a further aspect of this embodiment, the compositions have a Ni etch rate of approximately 600 or greater.

The disclosed and claimed cleaning compositions also have high Fe₂O₃ solubility.

In one embodiment, the disclosed and claimed cleaning compositions have an Fe₂O₃ solubility of approximately 2 mg/100 ml or greater to approximately 11 mg/100 ml or greater. In a further aspect of this embodiment, the compositions have an Fe₂O₃ solubility of approximately 5 mg/100 ml or greater to approximately 10 mg/100 ml or greater. In a further aspect of this embodiment, the compositions have an Fe₂O₃ solubility of approximately 2 mg/100 ml or greater. In a further aspect of this embodiment, the compositions have an Fe₂O₃ solubility of approximately 3 mg/100 ml or greater. In a further aspect of this embodiment, the compositions have an Fe₂O₃ solubility of approximately 4 mg/100 ml or greater. In a further aspect of this embodiment, the compositions have an Fe₂O₃ solubility of approximately 5 mg/100 ml or greater. In a further aspect of this embodiment, the compositions have an Fe₂O₃ solubility of approximately 6 mg/100 ml or greater. In a further aspect of this embodiment, the compositions have an Fe₂O₃ solubility of approximately 7 mg/100 ml or greater. In a further aspect of this embodiment, the compositions have an Fe₂O₃ solubility of approximately 8 mg/100 ml or greater. In a further aspect of this embodiment, the compositions have an Fe₂O₃ solubility of approximately 9 mg/100 ml or greater. In a further aspect of this embodiment, the compositions have an Fe₂O₃ solubility of approximately 10 mg/100 ml or greater. In a further aspect of this embodiment, the compositions have an Fe₂O₃ solubility of approximately 11 mg/100 ml or greater.

Method of Use

The disclosed and claimed subject matter further includes using the disclosed and claimed cleaning compositions for the removal of one or more metal containing layers in a mask-protective structure for EUV lithography. The EUV mask-protective structure may include any number of layers on a semiconductor device that are deposited or formed and removed or partially removed by methods that are known to a person of ordinary skill in the art, such as by one or more depositing steps, then one or more lithography steps, then one or more wet or dry etching steps, etc. The one or more layers may be present between the semiconductor substrate and the EUV mask. The semiconductor device on which the EUV mask and EUV mask-protective structure (the mask-protective structure may be referred to as a “pellicle structure”) are present may also include any number of layers of materials thereon in addition to the EUV mask and EUV mask-protective structure.

Thus, in another aspect, the disclosed and claimed subject matter relates to methods for fabricating a semiconductor device that includes the steps of:
a. forming one or more layers over a silicon substrate where at least one of those layers includes a Ni-containing layer; and
b. removing said Ni-containing layer by contacting the Ni-containing layer with at least one of the compositions of the disclosed and claimed subject matter.

In another aspect, the disclosed and claimed subject matter relates to methods of removing a metal-containing layer of a pellicle structure including the steps of:
a. providing a semiconductor device including a substrate and an EUV mask and a metal-containing EUV mask-protecting structure;
b. exposing the semiconductor device to EUV radiation; and
c. removing the metal-containing EUV mask-protecting structure by contacting the semiconductor device with at least one of the compositions of the disclosed and claimed subject matter. In a further aspect of this embodiment, the method includes one or more of the following additional steps:
d. depositing said metal-containing EUV mask-protecting structure on said semiconductor device via atomic layer deposition (ALD), e-beam evaporation, chemical vapor deposition or electroplating; and
e. performing a selective dry etch process on at least one portion of the semiconductor device prior to the removing step c.

In one embodiment, the EUV mask-protective structure can include multiple layers at least one of which includes a metal-containing layer that may be a film or a mesh or any kind of metal-containing layer. In a further aspect, the metal-containing layer may be a linking layer or a heat dissipation layer.

In a further embodiment, the one or more metal-containing layers may be applied by atomic layer deposition (ALD), by e-beam evaporation or chemical vapor deposition (CVD) or electroplating or any method known to a person of skill in the art for depositing or otherwise forming a metal on a surface.

In a further embodiment, the EUV pellicle structure may include one or more of the following: an EUV transmission layer, a graphene layer (that may be formed on the EUV transmission layer), a linking pattern provided on a defect, and/or a heat dissipation layer that may be on the graphene layer. In a further aspect of this embodiment, the graphene layer may include a polycrystalline structure. In a further aspect of this embodiment, the linking pattern may include connecting crystals of the graphene layer of a polycrystalline structure. Additional sacrificial layers made of polymer may be added too.

In a further embodiment, the EUV pellicle structure may include a metal layer or metal wire mesh layer.

In a further embodiment, the EUV pellicle structure may additionally or alternatively include one or more of the following layers: insulating layer(s), passivation layer(s), graphene layer(s), linking layer(s), EUV transmission layer(s), and heat dissipation layer(s) provided one layer or portion of a layer is a metal-containing layer. In a further aspect of this embodiment, the semiconductor device may include a substrate onto which the layers are deposited or formed, such as a silicon substrate.

In a further embodiment, the heat dissipation layer includes molybdenum and/or zirconium and/or include a material having an emissivity of 0.1 or more at a temperature of 700K or more. Thus, for example, in some aspects of this embodiment the heat dissipation layer may include titanium (Ti), tantalum (Ta), tungsten (W), molybdenum (Mo), chromium (Cr), cobalt (Co), boron (B), and carbon (C), nickel (Ni) and oxides and mixtures thereof. In other aspects of this embodiment, the heat dissipation layer may include gold (Au), platinum (Pt), mixtures thereof, and carbon nanostructures.

In a further embodiment, the heat dissipation layer includes a material having a high heat emissivity and excellent chemical resistance against hydrogen may be formed on the linking pattern. The heat dissipation layer minimizes the thermal deformation of the EUV pellicle structure that would otherwise be caused by the EUV radiation. By doing so, it is possible to improve the reliability and life characteristics of the pellicle structure. In addition, the linking pattern and/or the heat dissipation layer may be formed of materials providing low extinction coefficient values, high transmittance for EUV light, high mechanical strength and thermal stability. In one embodiment, the heat dissipation layer includes metal, for example, nickel (Ni).

In a further embodiment, the EUV mask protective structure may include an EUV transmission layer that includes a material having an extinction coefficient of 0.01 or less for EUV. In such an embodiment, the EUV transmission layer may include beryllium (Be), boron (B), carbon (C), silicon (Si), and phosphorus (P), Sulfur (S), potassium (K), calcium (Ca), scandium (Sc), bromine (Br), rubidium (Rb), strontium (Sr), yttrium (Y), zirconium (Zr), niobium (Nb), molybdenum (Mo), barium (Ba), lanthanum (La), cerium (Ce), praseodymium (Pr), and uranium (U). In such an embodiment, the EUV transmission layer may also include oxides, nitrides, carbides, or borides of materials having an extinction coefficient of 0.01 or less for the EUV described above, which are stabilized compounds of materials having an extinction coefficient of 0.01 or less and/or emissivity of 0.1 or more at a temperature of 700K or more.

In a further embodiment, the EUV mask protective structure may include a graphene layer. In such an embodiment, the graphene layer may be formed on the EUV transmission layer. In one aspect of this embodiment, the graphene layer may be formed on the EUV transmission layer by chemical vapor deposition (CVD), atomic layer deposition (ALD), or the like. When formed by one of these processes, the graphene layer may have a polycrystalline structure. Accordingly, the graphene layer may include a plurality of defects, such as a point defect such as a vacancy existing in the graphene layers or a line defect existing in the graphene layers or crystal grain boundaries due to changing crystal orientations.

In a further embodiment, the EUV mask protective structure may include a heat dissipation layer alone or with other layers. In such an embodiment, the heat dissipation layer may be formed on a linking pattern. In one aspect of this embodiment, the heat dissipation layer may be formed by e-beam evaporation. If the heat dissipation layer is formed on a linking pattern by a plasma process or a thermal evaporation process, it may be difficult to deposit a material having high transmittance to EUV. On the other hand, when the heat emission layer is formed on a linking pattern through an electron beam deposition method, a material having a high transmittance with respect to EUV is produced such that that the EUV pellicle structure also has high transmittance.

In a further embodiment, the heat dissipation layer may include a material having a high heat emissivity, low extinction coefficient value, and a coefficient of thermal expansion similar to that of the linking pattern (if present) in order to minimize thermal deformation of the EUV pellicle structure. In such an embodiment, the heat dissipation layer may be formed of a material that has excellent chemical resistance to hydrogen, thereby providing a pellicle structure with improved reliability and lifespan characteristics. In one aspect of this embodiment, the heat dissipation layer may include a material having a coefficient of thermal expansion similar to that of the linking pattern.

In a further embodiment, the heat dissipation layer and/or the linking layer, as described above, may include molybdenum and/or zirconium and/or other metal or metals. In addition, according to one embodiment, the heat dissipation layer in addition to molybdenum and zirconium, may include a material having an emissivity of 0.1 or more at a temperature of 700K or more. The heat dissipation layer may be formed by the electron beam evaporation method that is easy to deposit a material having a high transmittance to EUV. The EUV pellicle structure according to one embodiment of the disclosed and claimed subject matter may be used to protect a mask used in EUV lithography for manufacturing various semiconductor devices.

In some embodiments, the EUV protective structure may include nickel, alone or with other metals.

### Examples

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

Materials and Methods:

All chemicals utilized here are commercially available (e.g., from Sigma-Aldrich).

Acids were weighed and dissolved in DIW in a beaker. If a second acid was used it was added slowly to the solution. Oxidizer, and then the rest of the components, were added to the solution. The solution was stirred to evenly to dissolve solid reagents and create a homogeneous mixture. The mixture was heated to the specified temperature.

At the testing temperature, wafers were dipped into the mixture for the time period indicated in the following examples. The wafers were then removed from the mixture and rinsed with DIW for about 3 minutes. The rinsed wafers were then subjected to drying under nitrogen gas. The dried wafers were tested. The etch rates were measured at temperatures noted in the examples, between about 25° C. to about 50° C., and the time frame for etching Ni was 0 to about 1 minute, and the time frame for etching silicon oxide (SiOx) and silicon nitride (SiNx) was about 10 minutes.

The etch rates of Ni were measured using a ResMap 4-point probe resistivity meter and the etching rates of silicon oxide and silicon nitride were measured using a Filmtek PAR 2000SE from Scientific Computing International. The etch rates were calculated by the thickness difference before and after treatment, divided by immersion time.

Separately, the solubility of the metal oxides was measured using a weighing method, keeping dissolved iron oxide in the solution until the solution became heterogenous.

In the tables below, acid numbers appearing in parentheses (e.g., “(30.8)”) are neat acid values if such acid is present in the exemplified embodiment.

Example Formulations

The following example formulations demonstrate representative embodiments of the disclosed and claimed subject matter which provides a metal etching composition and method that has high removability rates, such as greater than 300 Å/min, or greater than 400 Å/min and some greater than 500 Å/min at 30° C. These etching compositions also provide good Fe₂O₃ solubility of greater than 2 mg/100 mL (i.e., greater than 2 mg Fe₂O₃ could be dissolved in 100 mL of the example formulations). These etching compositions also provide good compatibility with silicon nitrate (Si₃N₄) and silicon oxide (SiO₂) and other materials on the semiconductor substrate. The etch rates of the silicon nitrate is less than 1 Å/min at 30° C.

In Table 1, three acid component formulations including H2504 as a strong acid, HNO₃ as an oxidant and HCl as a second acid and a halogen source (chloride source) were tested. They all provided more than 340 Å/min metal (Ni) etching rate at 30° C. and had good metal oxide (Fe₂O₃) solubility more than 8 mg/100 mL. NH₄Cl can also act as a halogen source (chloride source) to help improve metal chelation and metal oxide (Fe₂O₃) solubility. Example 2 has the best metal oxide (Fe₂O₃) solubility with extra 2% of NH₄Cl. These three acid components all give good silicon oxide and SiN compatibility. The bath life of Example 4 was tested and had a long bath life with more than 168 hours at 30° C. without loss its metal (Ni) etching ability.

TABLE 1

| Component | Ex. 1 | Ex. 2 | Ex. 3 | Ex. 4 |
|---|---|---|---|---|
| HNO₃ (60%) | 1 (0.6) | 1 (0.6) | 1 (0.6) | 1.5 (0.9) |
| H₂SO₄ (97%) | 40 (38.8) | 40 (38.8) | 40 (38.8) | 40 (38.8) |
| HCl (35%) | 13.5 (4.725) | 13.5 (4.725) | 10 (3.5) | 10 (3.5) |
| Total Acid | 54.5 (44.125) | 54.5 (44.125) | 51 (42.9) | 51.5 (43.2) |
| NH₄Cl | 0 | 2 | 0 | 0 |
| DIW | 45.5 | 43.5 | 49 | 48.5 |
| Ni E/R 30° C. | 341.3 | 349.6 | 347.6 | 362.1 |
| (Å/min) | | | | |
| Silicon Oxide E/R | <1 | <1 | <1 | <1 |
| 30° C. (Å/min) | | | | |
| SIN E/R 30° C. | <1 | <1 | <1 | <1 |
| (Å/min) | | | | |
| Solubility of Fe₂O₃ | 9.5 mg/ | 10 mg/ | 8.5 mg/ | 8.5 mg/ |
| | 100 ml | 100 ml | 100 ml | 100 ml |

The examples in Table 2 show that H₂SO₄ and HNO₃ have high Ni etching rates. Without chloride ions, the metal oxide (Fe₂O₃) solubility was less than 2 mg/100 mL.

TABLE 2

| Component | Ex. 5 | Ex. 6 | Ex. 7 | Ex. 8 |
|---|---|---|---|---|
| HNO₃ (60%) | 1.5 (0.9) | 1.5 (0.9) | 1.5 (0.9) | 1.5 (0.9) |
| H₂SO₄ (97%) | 35 (33.95) | 40 (38.8) | 45 (43.65) | 50 (48.5) |
| Total Acid | 36.5 (34.85) | 41.5 (39.7) | 46.5 (44.55) | 51.5 (49.4) |
| DIW | 63.5 | 58.5 | 53.5 | 48.5 |
| Ni E/R 30° C. | 677 | 699 | 984 | 1450 |
| (Å/min) | | | | |
| Ni E/R 25° C. | 300 | 384 | 423 | 680 |
| (Å/min) | | | | |
| Silicon Oxide E/R | <1 | <1 | <1 | <1 |
| 30° C. (Å/min) | | | | |
| SIN E/R 30° C. | <1 | <1 | <1 | <1 |
| (Å/min) | | | | |
| Solubility of Fe₂O₃ | <2 mg/ | <2 mg/ | <2 mg/ | <2 mg/ |
| | 100 ml | 100 ml | 100 ml | 100 ml |

Table 3 compares ammonium persulfate (APS) and 2,5-dihydroxy-1,4-benzoquinone (oxidants) in H₂SO₄ or HCl system. In an H₂SO₄ system, APS provides a higher metal (Ni) etching rate than 2,5-dihydroxy-1,4-benzoquinone. APS and 2,5-dihydroxy-1,4-benzoquinone both give high metal (Ni) etching rates with HCl and better metal oxide (Fe₂O₃) solubility too.

TABLE 3

| Component | Ex. 9 | Ex. 10 | Ex. 11 | Ex. 12 |
|---|---|---|---|---|
| HNO₃ (60%) | 0 (—) | 0 (—) | 0 (—) | 0 (—) |
| H₂SO₄ (97%) | 40 (38.8) | 40 (38.8) | 0 (—) | 0 (—) |
| HCl (35%) | 0 (—) | 0 (—) | 50 (17.5) | 50 (17.5) |
| Total Acid | 40 (38.8) | 40 (38.8) | 50 (17.5) | 50 (17.5) |
| APS | 1 | 0 | 1 | 0 |
| 2,5-Dihydroxy-1,4- | 0 | 0.01 | 0 | 0.01 |
| benzoquinone | | | | |
| DIW | 59 | 59.99 | 49 | 49.99 |
| Ni E/R 30° C. | 695.5 | 162.6 | 699.17 | 667.2 |
| Solubility of Fe₂O₃ | 2 mg/ | 2 mg/ | 10.5 mg/ | 10.5 mg/ |
| | 100 ml | 100 ml | 100 ml | 100 ml |

In Table 4, methane sulfonic acid (MSA) gave high metal (Ni) etching rate and good metal oxide (Fe₂O₃) solubility. MSA and 2,5-dihydroxy-1,4-benzoquinone together in a formulation gives the highest metal (Ni) etching rate and good metal oxide (Fe₂O₃) solubility.

TABLE 4
MSA Based Formulations

| Component | Ex. 13 | Ex. 14 | Ex. 15 |
|---|---|---|---|
| HNO₃ (60%) | 1 (0.6) | 1.5 (0.9) | 0 (—) |
| HCl (35%) | 13.5 (4.725) | 10 (3.5) | 10 (3.5) |
| Total Acid | 14.5 (5.325) | 11.5 (4.4) | 10 (3.5) |
| 2,5-Dihydroxy-1,4- | 0 | 0 | 0.01 |
| benzoquinone | | | |
| MSA | 40 | 40 | 40 |
| DIW | 45.5 | 48.5 | 49.99 |
| Ni E/R 30° C. | 531.9 | 524.3 | 693.7 |
| Solubility of Fe₂O₃ | 9.5 mg/100 ml | 8.5 mg/100 ml | 8.5 mg/100 ml |

The embodiments of the disclosed and claimed subject matter have been disclosed above for illustrative purposes. Those skilled in the art will appreciate that various modifications, additions and substitutions are possible, without departing from the scope and spirit of the disclosed and claimed subject matter as disclosed in the accompanying claims.

1. A composition comprising:
water;
one or more oxidizing agents comprising between approximately 0.1 wt % and approximately 1.0 wt % of neat nitric acid;
(iii) one or more acids other than the nitric acid; and
(iv) one or more halogen ion source.

2-4. (canceled)

5. The composition of claim 1, further comprising (v) one or more chelating agent.

6. (canceled)

7. (canceled)

8. The composition of claim 1, wherein the one or more oxidizing agents further comprises one or more of peroxomonosulfate, perborate, perchlorate, perchloric acid, peracetate anions, periodate, persulfate, permanganate, chromate, dichromate, benzoquinones, and an amine-N-oxide.

9. The composition of claim 1, wherein the one or more oxidizing agents further comprises one or more of ammonium persulfate, 2,5-dihydroxy-1,4-benzoquinone, nitrosylsulfuric acid, and pyridine N-oxide, 4-methylmorpholine-N-oxide.

10. The composition of claim 1, wherein the one or more acids comprises one or more of sulfuric acid, hydrochloric acid, methane sulfonic acid, 4 methylbenzenesulfonic acid, hydrobromic acid, citric acid, malonic acid, hydrofluoric acid, acetic acid, phosphoric acid and hydroiodic acid.

11-35. (canceled)

36. The composition of claim 1, wherein a total wt % of neat acid in the composition is approximately 30 wt % to approximately 45 wt %.

37. The composition of claim 1, wherein a total wt % of neat acid in the composition is approximately 35 wt % to approximately 45 wt %.

38-43. (canceled)

44. The composition of claim 1, wherein the one or more acids comprises approximately 39.2 wt % of neat sulfuric acid.

45-52. (canceled)

53. The composition of claim 1, wherein the one or more acids comprises approximately 3.5 wt % of neat hydrochloric acid.

54. (canceled)

55. (canceled)

56. The composition of claim 1, wherein the one or more acids comprises sulfuric acid and hydrochloric acid.

57-61.

62. The composition of claim 1, wherein the one or more acids comprises approximately 39.2 wt % of neat sulfuric acid and of approximately 3.5 wt % of neat hydrochloric acid.

63-67.

68. The composition of claim 1, wherein the composition comprises water, approximately 33.5 wt % to approximately 50 wt % of neat sulfuric acid and approximately 0.9 wt % of neat nitric acid.

69-73.

74. The composition of claim 1, wherein the composition comprises water, approximately 3.0 wt % to approximately 5.0 wt % of neat hydrochloric acid and approximately 0.6 wt % to approximately 0.9 wt % of neat nitric acid.

75-79.

80. The composition of claim 1, wherein the composition comprises water, approximately 3.0 wt % to approximately 5.0 wt % of neat hydrochloric acid, approximately 0.6 wt % to approximately 0.9 wt % of neat nitric acid and approximately 33.5 wt % to approximately 50 wt % of neat sulfuric acid.

81-97. (canceled)

98. The composition of claim 1, wherein the composition comprises water and approximately 40 wt % to approximately 45 wt % combined of neat sulfuric acid, neat hydrochloric acid and neat nitric acid.

99. (canceled)

100. (canceled)

101. The composition of claim 1, wherein the composition comprises water and approximately 43 wt % to approximately 45 wt % combined of neat sulfuric acid, neat hydrochloric acid and neat nitric acid.

102-112. (canceled)

113. The composition of claim 1, wherein the composition comprises water, approximately 39.2 wt % of neat sulfuric acid, approximately 3.5 wt % of neat hydrochloric acid and approximately 0.9 wt % of neat nitric acid.

114. The composition of claim 1, wherein the composition consists essentially of water, approximately 39.2 wt % of neat sulfuric acid, approximately 3.5 wt % of neat hydrochloric acid and approximately 0.9 wt % of neat nitric acid.

115. The composition of claim 1, wherein the composition consists of water, approximately 39.2 wt % of neat sulfuric acid, approximately 3.5 wt % of neat hydrochloric acid and approximately 0.9 wt % of neat nitric acid.

116-124. (canceled)

125. The composition of claim 1, wherein the one or more halogen ion source comprises one or more of hydrobromic acid, hydroiodic acid hydrogen chloride, hydrofluoric acid, hydrochloric acid, ammonium chloride, ammonium bromide, ammonium fluoride and ammonium iodide.

126. The composition of claim 1, wherein the one or more halogen ion source comprises one or more of ammonium chloride, ammonium bromide, ammonium fluoride and ammonium iodide.

127-150. (canceled)

151. The composition of claim 1, wherein the composition has an Fe₂O₃ solubility of approximately 2 mg/100 ml or greater to approximately 11 mg/100 ml or greater.

152. (canceled)

153. (canceled)

154. A method of removing a metal-containing layer of a pellicle structure comprising the steps of:
a. providing a semiconductor device comprising a substrate, an EUV mask and a metal-containing EUV mask-protecting structure comprising nickel;
b. exposing the semiconductor device to EUV radiation; and
c. removing the metal-containing EUV mask-protecting structure by contacting said semiconductor device to the composition of claim 1.

155-161. (canceled)
